(19) United States
(12) Patent Application Publication
(10) Pub. No.: US 2002/0075935 A1
(43) Pub. Date: Jun. 20, 2002

(54) Lateral optical pumping of vertical cavity surface emitting laser

(76) Inventor: Richard D. Clayton, Kanata (CA)

Correspondence Address: Gowling Lafleur Henderson LLP, Suite 2600, 160 Elgin Street, Otawa, ON, K1P 1C3, CA

(21) Appl. No.: 10/013,522

(22) Filed: Dec. 13, 2001

(30) Foreign Application Priority Data
Dec. 15, 2000 (CA) 2,328,637

(51) Int. Cl. H01S 5/00; H01S 3/091; H01S 3/094; H01S 3/08

(52) U.S. Cl. 372/75; 372/45; 372/96

(57) ABSTRACT

An optically pumped monolithic VCSEL (vertical cavity surface emitting laser) architecture is disclosed. The laser structure comprises at least one signal VCSEL, at least one pump laser, and transition regions between the signal VCSELs and the pump lasers The signal VCSEL is laterally optically pumped by the pump laser, which can be electrically or optically pumped. The signal VCSEL, the pump laser and the transition region all are monolithically integrated onto a common substrate. The signal VCSEL can be disposed outside or inside the pump laser cavity (extra-cavity or intra-cavity pumping). The cavity of the pump laser can takes various forms, such as a concave cavity, a confocal cavity, or a cylindrical or ellipsoidal form of cavity. Several signal VCSEL can be disposed in the focus or focal area of the cavity of the pump laser.

### FIELD OF THE INVENTION

The present invention relates to a vertical cavity surface emitting laser, and particularly relates to an improved vertical cavity surface emitting laser architecture being laterally optically pumped by a pump laser which is monolithically integrated with the vertical cavity surface emitting laser.

### BACKGROUND OF THE INVENTION

Vertical cavity surface emitting lasers (hereinafter, referred to as VCSEL) are considered desirable and are widely used for many optical communications applications. However, there have been some difficulties associated with the fabrication of high efficiency VCSELs. For instance, electrical pumping of the gain region (active region) of VCSELs can be problematic due to the conflicting requirements of the reflective mirrors and the electrical injection process. Specifically, the mirrors typically need to have higher dielectric properties, while the current injection path should be of lower resistance electrically. Therefore, the reflectivity of the mirrors compromises their conductances and vice versa. Moreover, the electrical pumping of the VCSELs inevitably requires p and n dopants inside of the optical cavity, which means a reduction in the optical efficiency and, consequently, limitation of the output power.

An alternative measure to overcome these problems is optical pumping technology, in which a separate pump laser is provided for pumping optically the VCSEL, which is called a signal laser with respect to the pump laser This technology usually, however, requires separate production and alignment of the pump laser and the signal VCSEL. Furthermore, co-axial optical pumping of VCSELs is hampered by the constraints placed on the mirror filter functions and pump emission wavelengths Further complication and expense arise in the hybrid assembly of such systems in achieving the required alignment of the pump and signal laser For example, U.S. Pat. No. 5,513,204 issued on Apr. 30, 1996 discloses an optical pumped VCSEL configuration as shown in FIG. 1, where a signal VCSEL 2 is vertically and coaxially aligned with a pump VCSEL 4. The optically pumped signal VCSEL 2 consists of an active region 2a interposed between a top mirror 2b and a bottom mirror 2c and emits a long wavelength radiation 8. The electrically pumped pump VCSEL, likewise, consists of an active region 4a between a pair of mirrors 4b, 4c and emits a short wavelength radiation 6 as pumping light for the active region 2a of the signal VCSEL 2. In fabricating this prior art configuration, co-axial alignment is unavoidable between the two VCSELs 2, 4, and bonding 3 between them, such as optical transparent adhesive, wafer-fusion or metal-to-metal bonding is inevitably required All of these consequently lead to complicated manufacturing processes and cost increases Also, in operation, the pumping light 6 must pass through the bottom mirror 2c of the signal VCSEL 2 in order for it to be transmitted to and pump the active region 2a of the signal VCSEL 2. Passing of light 6 through the mirror 2c and the bonding 3 can lead to a reduction in the optical efficiency of the pumping light due to parasitic reflection, absorption, and so on. In addition, high brightness operation of the pump VCSEL 4 is more difficult than for edge emitting lasers, and separating the pump 4 from the signal VCSEL 2 enough to achieve sufficient thermal isolation may result in inefficient illumination of the signal VCSEL 2.

Accordingly, it is an object of the present invention to provide an improved VCSEL structure being laterally optically pumped by a pump laser which is monolithically integrated with the VCSEL.

It is another object of the present invention to provide a laterally optically pumped VCSEL structure, which can be efficiently pumped by a pump laser which allows greater flexibility in its selection from conventional laser architectures.

It is another object of the present invention to provide a laterally optically pumped VCSEL structure, which can be compact, easily fabricated, and high-powered

### SUMMARY OF THE INVENTION

In accordance with the present invention, there is provided an improved laser device, which comprises at least one signal vertical cavity surface emitting laser (a signal VCSEL) and at least one pump laser, wherein the signal VCSEL is laterally optically pumped by the pump laser. Each signal VCSEL has an active region, an upper mirror, and a lower mirror, and each pump laser has a cavity which includes at least one active region. Preferably, the pump laser is monolithically integrated with the signal VCSEL.

Also, the laser device of the invention may further comprise a transition region between the signal VCSEL and the pump laser. The transition region is monolithically integrated with the signal VCSEL and the pump laser as well, and is of higher energy bandgap than the pump laser emission energy. The transition region behaves as a waveguide for emission from the pump laser, as a barrier to the inter-diffusion of charge carriers between the pump laser and the signal VCSEL, and as a barrier for avoiding thermal crosstalk between the signal VCSEL and the pump laser.

In accordance with one feature of the invention, the signal VCSEL may be disposed inside or outside of the cavity of the pump laser, thereby canying out an intracavity or extra-cavity pumping by the pump laser Preferably, the pump lasers may be electrically or optically pumped, or a combination of electrically and optically pumped lasers.

In accordance with another feature of the invention, the cavity of the pump laser may be formed with plane mirrors Also, the pump laser may comprise a concave cavity formed with curved mirrors so that a pumping light from the pump laser can be focused onto an active region of the signal VCSEL. Preferably, the concave cavity may include a confocal cavity formed by mirrors having different curvatures from each other. The cavity of the pump laser may include a convex cavity.

In accordance with another feature of the invention, the cavity of the pump laser may have a cylindrical form. Also, the cavity may have the form of ellipsoid, or the form of partial ellipsoid, so that the signal VCSEL can be disposed at one focal point of the ellipsoid and the pump laser in the other focal point of the ellipsoid.

According to the present invention, there is also provided an array of laser devices which comprises the laser device described above. The array may be one- or two-dimensional. Furthermore, according to the invention, there is provided an optoelectronic package which includes the laser device described above, where the laser device may be monolithically integrated with the package.

According to the present invention, there is provided a method of operating a VCSEL, which comprises a step of pumping the VCSEL laterally optically with a light emitted from a pump laser. The method further comprises a step of providing a monolithic integration of the VCSEL and the pump laser. Also, the method further comprises a step of providing a transition region between the VCSEL and the pump laser, in which a monolithic integration of the VCSEL, the pump laser, and the transition region may be provided.

According to other features of the invention, many possible resonator structures are possible to efficiently couple the pump laser to the signal VCSEL, the key attributes are good pumping efficiency, spatially localized pumping of the VCSEL, isolation of the heat and carriers of the pump laser from the signal VCSEL, low optical noise from the VCSEL. While a few of the most preferred configurations and methods for producing them will be presented, such as arrangements of nominally linear cavities and circular or related cavities, it should be understood that there are many other resonator structures and methods of achieving them without departing from the gist of the present invention. Therefore, the following description indicates desirable examples rather than the totality of approaches. As is usually the case in semiconductor fabrication, the most desirable method for producing a component many be influenced by the equipment at hand: as such the examples are presented assuming a typical set of equipment for fabrication, and do not include exhaustive optimization for every manufacturing eventuality.

A further understanding of the other features, aspects, and advantages of the present invention will be realized by reference to the following description, appended claims, and accompanying drawings.

### BRIEF DESCRIPTION OF THE DRAWINGS

The embodiments of the invention will now be described with reference to the accompanying drawings, in which

FIG. 1 is a schematic representation of a prior art configuration in which two VCSELs are coaxially aligned and physically bonded together;

FIG. 2 is a schematic representation showing a conceptual configuration of the present invention;

FIG. 3 is a schematic representation of a first embodiment with a pump laser monolithically integrated therewith in accordance with the present invention;

FIG. 3a is a transverse sectional view of the FIG. 3;

FIG. 4 is a schematic representation of a second embodiment in accordance with the present invention, where a pump laser includes concaved mirrors;

FIG. 5 is a schematic representation of a third embodiment, in which a pair of active regions are monolithically integrated therewith in accordance with the present invention.

FIG. 5a is a transverse sectional view of the FIG. 5, and

FIG. 6a is a schematic representation of a fourth embodiment, in which a pair of pump lasers are monolithically integrated therewith in accordance with the present invention;

FIG. 7 is a schematic representation of a fifth embodiment, in which a cylindrical shape of pump laser is monolithically integrated therewith around a signal VCSEL in accordance with the present invention;

FIG. 7a is a vertical sectional view of the FIG. 7;

FIG. 8 is a schematic representation of a sixth embodiment, in which an elliptical shape of pump laser is monolithically integrated therewith around a signal VCSEL in accordance with the present invention;

FIG. 8a is a vertical sectional view of the FIG. 8;

FIG. 9 is a schematic representation of a seventh embodiment, in which the monolithically integrated pump laser is configured for extra-cavity pumping of the VCSEL signal laser; and

FIG. 9a is a transverse sectional view of the FIG. 9.

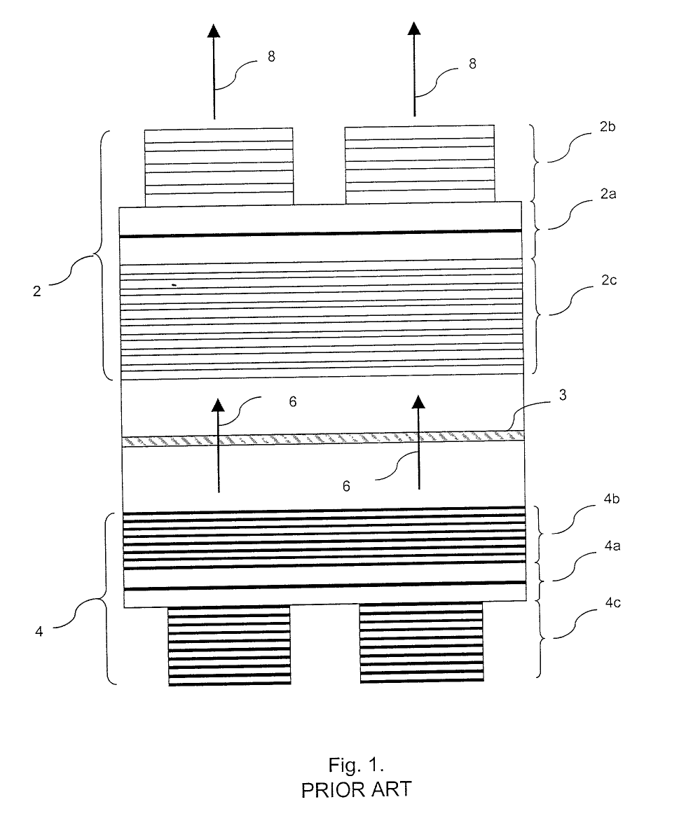

### DETAILED DISCLOSURE OF THE PREFERRED EMBODIMENT(S)

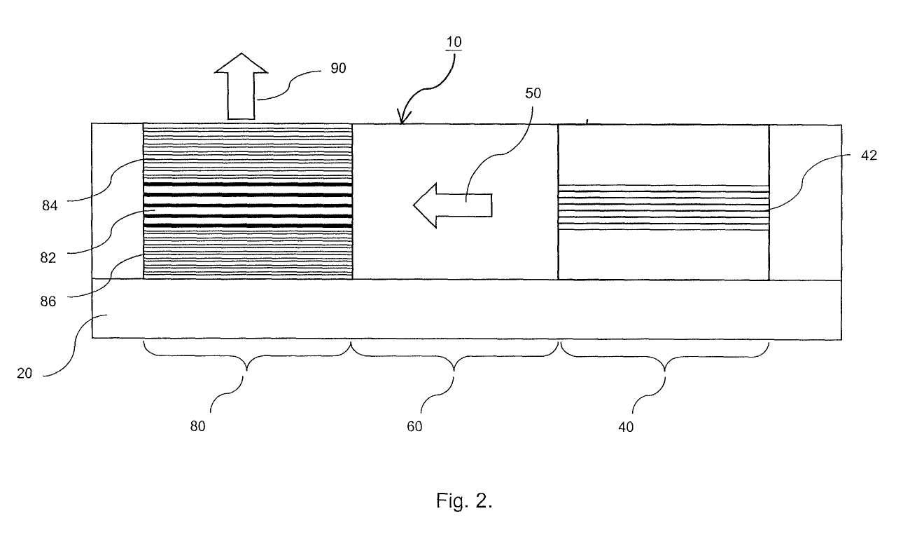

Before describing specific embodiments of the present invention, a basic concept of the present invention will be described with reference to FIG. 2, which shows a conceptual configuration of the optically pumped, vertical cavity surface emitting laser (VCSEL) having a lateral emission pump laser that is monolithically integrated onto a common substrate in accordance with the various principles of the invention.

Shown in FIG. 2 is a laser device 10 of the invention which comprises a pump laser 40 and a signal VCSEL 80, both of which are monolithically integrated into one piece onto a common substrate 20. The pump laser 40 may be an electrically or optically pumped, lateral emission laser, which constitutes an active region 42 sandwiched between two spacer or electric contacts, and reflective mirrors (not shown in FIG. 2) as in conventional electrically or optically pumped lasers. As will be understood by those skilled in the art, the reflective mirrors may be selected from a variety of choices such as a reflective surface, Bragg reflectors, photonic lattices or their variations. The signal VCSEL 80 includes an active region 82 interposed between an upper mirror 84 and a lower mirror 86. The terms “upper mirror” and “lower mirror” are well known in this laser device and do not require any particular spatial orientation of the device when in use. Likewise, these mirrors 84, 86 may be realized by many kinds of technologies, such as epitaxial layers, deposited dielectric layers, MEMS devices or any combinations of these or similar methods, as long as they are functional for the VCSEL operation. More specific configurations, functions and materials concerning the pump laser 40 and the signal VCSEL 80 will be described below in greater detail in conjunction with various embodiments of the invention.

Preferably, the laser device 10 may further comprise a transition region 60 between the pump laser 40 and the signal VCSEL 80, with all of which it is monolithically integrated onto the substrate 20. As will be further described below, the transition region 60 can play significant roles, like acting as a waveguide for pumping light, as a barrier to the diffusion of charge carriers from the gain region of the pump laser 40 or the signal VCSEL 80, and as a barrier against thermal crosstalk between the device components. A significant feature is that all the above noted components 40, 60, 80 are monolithically implemented onto the same common substrate 20 so that the laser device 10 can be made compact, more easily fabricated, and more reliable.

Briefly, in the operation of the device as shown in FIG. 2, optical radiation is emitted laterally from the active region 42 of the pump laser 40 which may be electrically or optically pumped, and then laterally injected into the active region of the signal VCSEL 80. The pump laser radiation acts as a pumping light 50 for the signal VCSEL 80. At this time, the transition region 60 acts as a waveguide for the pumping light 50. Also, it avoids the heat crosstalk between the pump laser 40 and the signal VCSEL 80 and the diffusion of charge carriers out of the signal VCSEL 80 and the pump laser 40, leading to enhancement in its efficiency. Finally, a device output 90 is generated from the signal VCSEL 80. More detailed operation of both intra-pump-cavity and extra-pump-cavity will be described below with reference to various embodiments of the invention.

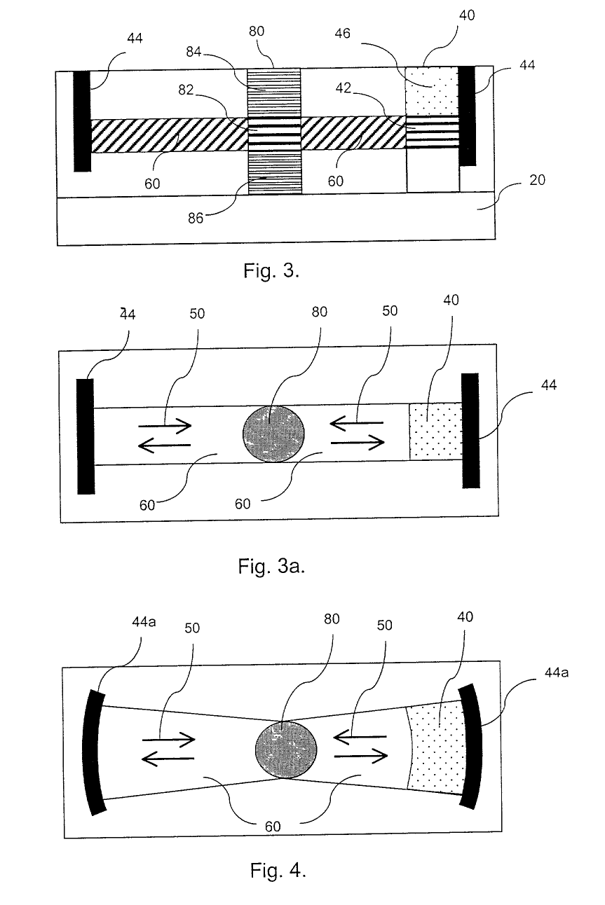

In FIGS. 3 and 3a, a first specific embodiment of a monolithically integrated VCSEL is shown, in which a signal VCSEL 80 and a pump laser 40 are provided on a common substrate 20, and a pair of reflective mirrors 44 for the pump laser are provided at both sides of the signal VCSEL 80 to achieve intra-pump-cavity pumping of the VCSEL 80. Two transition regions 60 are formed between the mirrors 44 as illustrated in FIGS. 3 and 3a. Accordingly, the active region 82 of the signal VCSEL 80, together with the transition regions 60 and the active region 42 of the pump laser, act as a waveguide for the emission from the pump laser 40, i.e., as a waveguide for the pumping light 50 as shown in FIG. 3a. These components 42, 60, and 82 may be referred to as a “waveguide region” for convenience of the description.

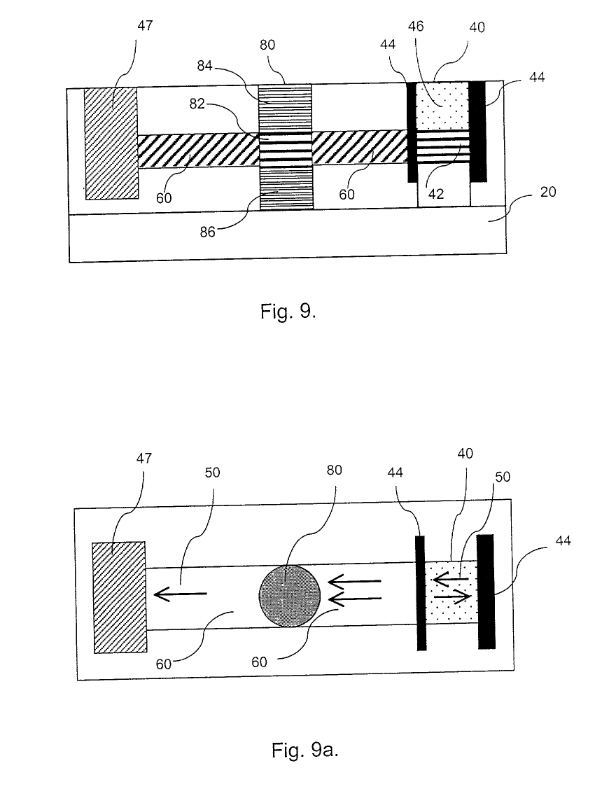

In the embodiment of FIGS. 3 and 3a, the active region 42 of the pump laser 40, which may be electrically or optically pumped, emits radiation. The radiation is amplified through stimulated emission while in the waveguide region 42, and then travels between the pair of mirrors 44 via the waveguide regions 42, 60, 82. While traveling between the pair of mirrors 44 as the pumping light 50, the radiation is partially absorbed by the active region 82 of the signal VCSEL 80 When sufficient pump radiation is absorbed in the VCSEL active region 82, the VCSEL 80 reaches the threshold condition and begins surface normal emission at the VCSEL wavelength as the device output 90 in FIG. 2. The radiation from the pump laser 40 must be of higher energy than that of the signal VCSEL 80 and, therefore, must be chosen for the optimum offset, depending on the application and fabrication technology choices. The pump laser 40 must provide the pumping light 50 to a suitable area of the appropriately configured VCSEL gain region 82 to ensure single transverse mode operation of the VCSEL 80. While the embodiment shown in FIGS. 3 and 3a carries out an intra-cavity pumping where the signal VCSEL 80 is disposed inside of the pump laser 40 cavity, as shown in FIGS. 9 and 9a, the signal VCSEL 80 may be disposed outside of the pump laser cavity so that an extra-cavity pumping can be carried out. Further details of the extra-cavity pumping will be described hereafter.

As those skilled in the art will understand, the various components of the device need to be sufficiently compatible to allow the monolithic integration, while being differentiated by their required functions. For example, the signal VCSEL 80 should have the layers designed for low optical losses, since the single pass gain is not large, and so, for example, should not have substantial p dopant concentration in the optical path, while the pump laser 40 requires the p doping for efficient electrical pumping. Optimum pump laser efficiency can be achieved when the active region 82 of the signal VCSEL 80 acts as a proper waveguide for the pumping light 50. The transition waveguide regions 60 and their interface with the VCSEL 80 should have low absorption and scattering losses for the pumping light (radiation) 50 and VCSEL radiation. These aspects of the transition region 60 can be realized through various processing methods, such as a conceptually straightforward multistage epitaxial growth of specifically designed layers, while other methods could involve selective bandgap modification through, for example, quantum well intermixing processes and p dopant diffusion, or various combinations of such processes.

Also, effective operation of the invention requires several design considerations, including optimizing the reflective mirror stacks 84, 86 for the signal VCSEL 80, positioning the active region 82 of the signal VCSEL at the optimum position relative to the standing wave resonating in the VCSEL cavity, ensuring the transition waveguide region 60 does not introduce substantial loss to the VCSEL mode or to the pump radiation, ensuring the radiation energy of the pump laser 40 effectively pumps the signal VCSEL 80, and producing a simple stable lateral pump laser cavity. As will be understood by those skilled in the art, these requirements for embodying the invention can be met by selecting appropriately from many conventional laser fabrication technologies and materials. Also, any conventional laser processing, such as the selective etching and epitaxial regrowth technology, can be used in order to fabricate the monolithic lateral optical pumping VCSEL of the invention.

In FIG. 4, a second embodiment of the monolithic optical pump VCSEL is shown, in which all the portions of it are the same as the first embodiment illustrated in FIG. 3 and 3a, with exception of the shape of reflective mirrors for the pump laser 40. As seen in FIG. 4, the mirrors 44a are concaved toward the active region 82 of the signal VCSEL 80 so that the pumping light 50 can be effectively concentrated onto the active region of the signal VCSEL 80 so as to pump it efficiently. The operation is similar to that of the first embodiment, except for the efficient focusing of pumping light onto the signal VCSEL to help control lateral modes of both the signal and pump lasers. The two mirrors 44a need not have the same radius of curvature the requirement is that the foci of the two mirrors be placed relative to each other (nominally coincident) to provide an efficient, low intensity noise pump laser. Tolerances and tradeoffs in the designed position of the mirrors and foci are available from various texts on laser resonator design and are well known to laser designers.

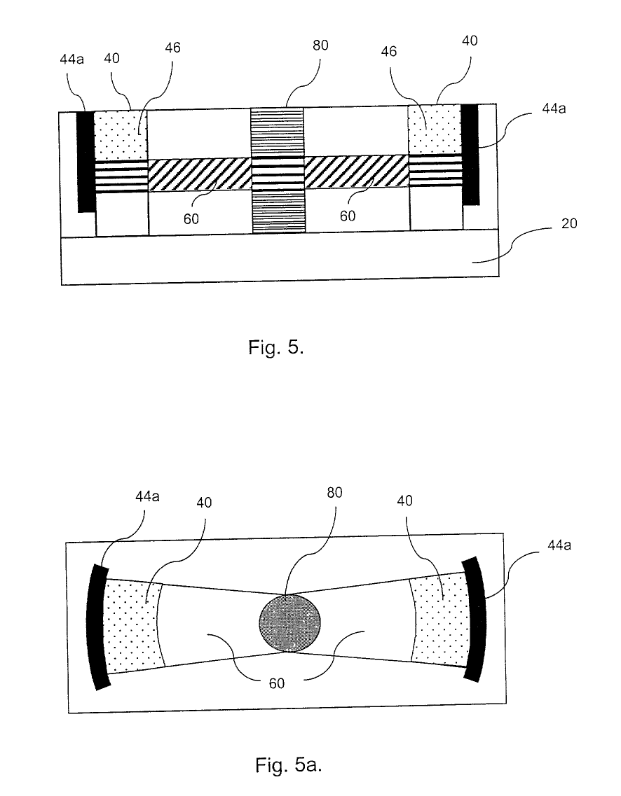

FIG. 5 and 5a illustrate a third embodiment of monolithic optical pump VCSEL configuration. In this embodiment, the pump lasers 40 is fabricated with two active regions 42 monolithically provided onto the same substrate 20 together with a signal VCSEL 80 and transition regions 60, and the remaining portions are similar to the first and second embodiments as shown in FIG. 3 and 3a, and FIG. 4 respectively. As depicted in FIG. 5a, the signal VCSEL 80 is placed at the center of the symmetric pump laser cavity, within the mirrors 44a. As noted above, however, the signal VCSEL 80 may be disposed outside of the cavity of the pump laser 40 so that an extra-cavity pumping can be accomplished by the pump laser. Similarly to the second embodiment of FIG. 4, the mirrors 44a may be concaved toward the active region 82 of the signal laser 80 for the same reason. In this embodiment, however, the two mirrors 44a may have different radius of curvatures from each other, so that two signal VCSELs may be disposed at each focal point of the curved mirrors Namely, a confocal cavity of the pump laser may be achieved. Also, it is possible that more than two signal VCSELs are disposed in the focal area of the concave or confocal cavity of the pump laser. The other operational features of this embodiment are similar to the previous embodiments, except that the signal VCSEL 80 will be more efficiently and powerfully pumped due to the action of the two pump gain regions 42.

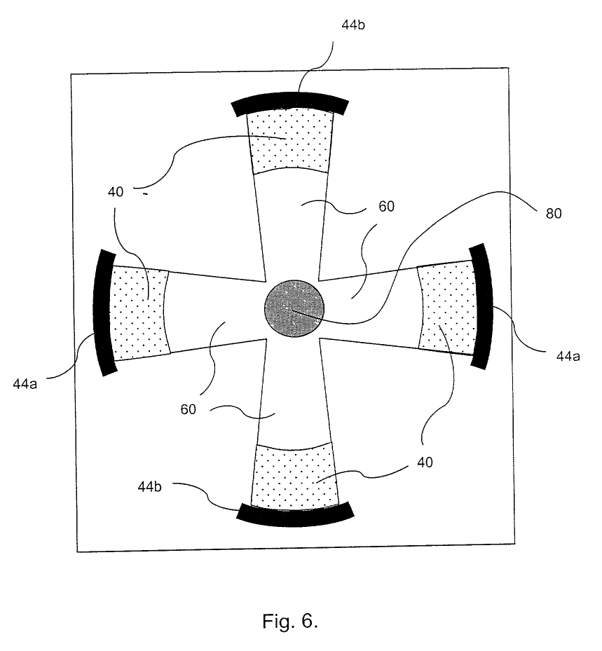

More than one pump laser may be provided so that more controlled and efficient pumping and consequently a more powerful output of the signal VCSEL can be realized. For example, FIG. 6 depicts an embodiment in which a pair of pump lasers 40 are provided, where the pump lasers 40 may be electrically or optically pumped, or a combination of electrically or optically pumped lasers. Likewise, the details of each component region and their operations are similar to or the same as those of the previous embodiments, for example, an extra-cavity and/or intra-cavity pumping may be carried out by the pump lasers, and the cavity of pump laser may include a concave cavity or a confocal cavity.

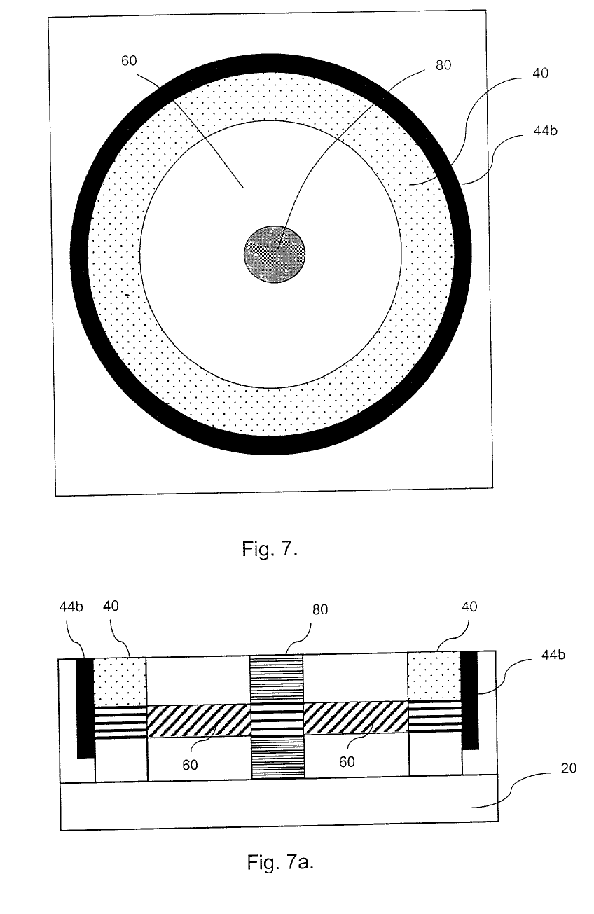

A mirror of cylindrical shape may be provided around the signal VCSEL so as to pump it more efficiently. As is illustrated in FIG. 7, this embodiment includes a cylindrically shaped pump laser 40, a cylindrically shaped mirror 44b provided around the cylindrical pump laser, and a signal VCSEL 80 disposed at the center of the mirror 44b, so that more efficient and intensive pumping of the signal VCSEL 80 can be realized. Likewise, the area between the signal VCSEL 80 and the cylindrical pump laser 40 serves to function as a transition region 60 which is also monolithically integrated with the signal VCSEL 80 and the reflective mirror 44b onto the substrate 20, as is illustrated in FIG. 7a which is a vertical sectional view of FIG. 7 As will be understood by those skilled in this art it is desirable that the signal VCSEL 80, the pump laser 40, and the transition region 60 is concentric with one another for more effective operation of the device. The other operational features of this embodiment will be similar to the previous embodiments, for example, except that the signal VCSEL 80 will be more efficiently and intensively pumped due to the circular shape of pump laser 40 It is important to note that care in the design of the pump resonator is required to ensure the appropriate operating spatial mode of the pump laser is achieved. An example would be a grating based mirror which would not support non-radial modes, or mode selective features for cavities formed with conventional mirrors.

In the embodiment shown in FIGS. 7 and 7a, the pump laser may take a ellipsoidal form to make a confocal cavity so that two signal lasers can be disposed at each focus. As noted above, more than two signal VCSELs may be disposed in the focal or confocal area of the cavity of the pump laser.

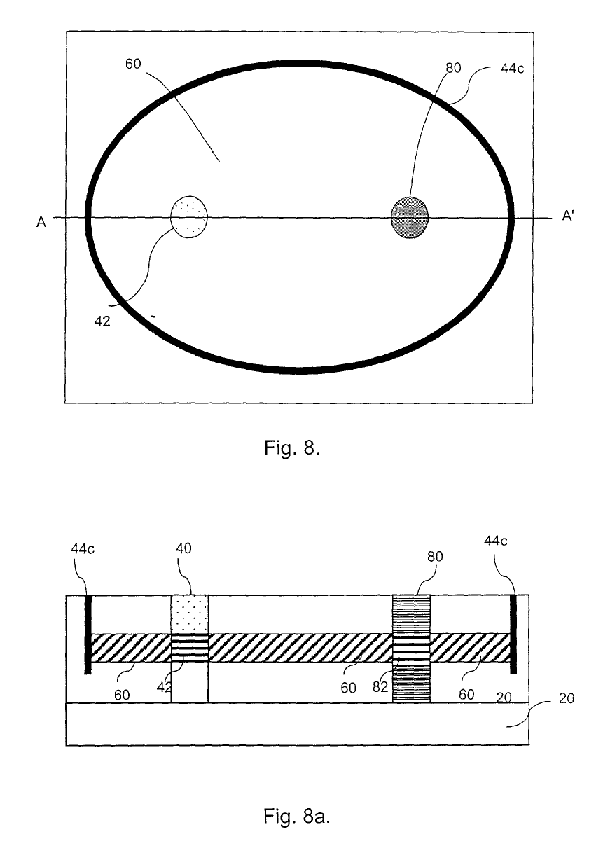

A mirror of elliptical shape may be provided around the signal VCSEL as an alternative pumping configuration. As is illustrated in FIG. 8, this embodiment includes an elliptically shaped pump laser 40, constructed from an elliptically shaped mirror 44c provided around the pump laser active region 42 and signal VCSEL 80. The pump and signal lasers are disposed at the foci of the elliptical cavity of the pump laser, which is defined by the elliptically shaped mirror 44b, so that more efficient and intensive pumping of the signal VCSEL 80 can be realized. Likewise, the area between the signal VCSEL 80 and the pump gain region 40 serves to function as a transition region 60 which is also monolithically integrated with the signal VCSEL 80 and the reflective mirror 44c onto the substrate 20, as is illustrated in FIG. 8a which is a vertical sectional view of FIG. 8. The operation of this embodiment will be similar to the previous embodiments, and the pump gain regions 42 may be disposed as shown or more similarly to the case of FIG. 7.

As noted above, the same basic structures may be applied to extra-pump-cavity pumping as well. Extra-cavity pumping requires the signal VCSEL be placed outside the feedback cavity of the pump laser, allowing the pump laser to oscillate in isolation. The output radiation from the pump laser is then coupled to the VCSEL structure. The above referenced structures can be modified to provide extra-cavity pumping of the VCSEL. The key changes involve ensuring the residual pump light from one pump source does not destabilize the other pump sources. An example of an extra-pump-cavity configuration is shown in FIG. 9. In such cases the signal VCSEL 80 is placed outside the pump laser resonator formed by the mirrors 44. An additional feature is the optical termination region 47, which is desired to ensure spurious reflections do not disrupt the operation of the pump laser 40. This region can be absorptive, reflective or scattering; the primary objective being to adequately reduce light returning to the pump laser 40. While the extra-pump-cavity pumping configuration is advantageous in establishing mode control of the pump source, it does not provide the same efficiency in use of pump photons.

While the present invention has been described with reference to several specific embodiments, the description is illustrative of the invention and is not to be construed as limiting the invention. Terms used herein such as “vertical” in relation to the signal VCSEL and “upper” and “lower” in relation to the mirrors are terms well known in this art and do not limit the invention to any particular orientation when in use Various modification may occur to those skilled in the art without departing from the true spirit and scope of the invention as defined by the appended claims.

For example, according to the present invention, a one- or two-dimensional array of the VCSEL laser described above may be provided, which is included in the scope of the present invention. Any optoelectronic package or application comprising the laser device described above may be provided, which is also included in the scope of the invention. As will be understood by those skilled in the art, the laser device of the package or application may be monolithically integrated into the package or application itself.

Furthermore, according to the present invention, there may be provided a method of operating a VCSEL, which comprises a step of pumping the VCSEL laterally with a light emitted from a pump laser The method further comprises a step of providing a monolithic integration of the VCSEL and the pump laser Also, the method further comprises a step of providing a transition region between the VCSEL and the pump laser, in which a monolithic integration of the VCSEL, the pump laser, and the transition region may be provided.

What is claimed is:

1. A laser device comprising
(a) a vertical cavity surface emitting laser (a signal VCSEL),
(b) a pump laser comprising a cavity, which includes at least one active region, and
(c) the signal VCSEL being laterally optically pumped by the pump laser.

2. A laser device according to claim 1, wherein the pump laser is monolithically integrated with the signal VCSEL.

3. A laser device according to claim 1, further comprising a transition region between the signal VCSEL and the pump laser.

4. A laser device according to claim 3, wherein the signal VCSEL, the pump laser, and the transition region are monolithically integrated with one another.

5. A laser device according to claim 1, wherein the signal VCSEL is disposed inside the cavity of the pump laser.

6. A laser device according to claim 1, wherein the signal VCSEL is disposed outside the cavity of the pump laser

7. A laser device according to claim 1, wherein the cavity of the pump laser includes a cavity having a cylindrical form.

8. A laser device according to claim 1, wherein the cavity of the pump laser includes a cavity having the form of an ellipsoid.

9. A laser device according to claim 8, wherein the signal VCSEL is disposed at one focal point of the ellipsoid.

10 A laser device according to claim 9, wherein the active region of the pump laser is disposed at the other focal point of the ellipsoid.

11. A laser device according to claim 1, wherein the cavity of the pump laser includes a cavity having the form of a portion of an ellipsoid which is capable of forming a resonator.

12. A laser device according to claim 11, wherein the signal VCSEL is disposed at one focal point of the ellipsoid.

13. A laser device according to claim 12, wherein the active region of the pump laser is disposed at the other focal point of the ellipsoid.

14. A laser device according to claim 1, comprising a plurality of pump lasers.

15. A laser device according to claim 1, wherein the cavity of the pump laser is formed with a plane mirror.

16. A laser device according to claim 1, wherein the cavity of the pump laser includes a concave cavity formed with a curved mirror.

17. A laser device according to claim 16, wherein the concave cavity includes a confocal cavity.

18. A laser device according to claim 1, wherein the cavity of the pump laser is formed with a plane mirror and a curved mirror.

19. A laser device according to claim 16, wherein the curved mirror is arranged so that a pumping light from the pump laser is focused onto an active region of the signal VCSEL.

20. A laser device according to claim 18, wherein the curved mirror is arranged so that a pumping light from the pump laser is focused onto an active region of the signal VCSEL.

21. A laser device according to claim 1, wherein the cavity of the pump laser includes a convex cavity.

22. A laser device according to claim 1, wherein the pump laser is electrically pumped.

23. A laser device according to claim 1, wherein the pump laser is optically pumped.

24. A laser device according to claim 1, wherein the pump laser is a combination of electrically and optically pumped lasers.

25. A laser device according to claim 3, wherein the transition region is of higher energy bandgap than the pump laser emission energy

26. A laser device according to claim 3, wherein the transition region and the active region of the signal VCSEL define a waveguide for emission from the pump laser.

27. A laser device according to claim 3, wherein the transition region defines a barrier to the inter-diffusion of charge carriers between the pump laser and the signal VCSEL.

28. A laser device according to claim 3, wherein the transition region defines a barrier for avoiding thermal crosstalk between the signal VCSEL and the pump laser.

29. An optoelectronic package comprising the laser device claimed in claim 1

30. An array of laser devices comprising the laser device claimed in claim 1

31. An array of laser devices according to claim 30, wherein the array of laser devices is one-dimensional.

32. An array of laser devices according to claim 30, wherein the array of laser devices is two-dimensional.

33. An optoelectronic package comprising the array of laser devices according to claim 30.

34. A method of operating a VCSEL comprising a step of pumping the VCSEL laterally optically with a light emitted from a pump laser.

35. A method according to claim 34, further comprising a step of providing a monolithic integration of the VCSEL and the pump laser.

36. A method according to claims 34, further comprising a step of providing a transition region between the VCSEL and the pump laser

37. A method according to claim 36, further comprising a step of providing a monolithic integration of the VCSEL, the pump laser, and the transition region.
